(19) United States
(12) Patent Application Publication
(10) Pub. No.: US 2015/0219105 A1
(43) Pub. Date: Aug. 6, 2015

(54) ROTATING FLOW GENERATOR, PLUMBING SYSTEM, SEMICONDUCTOR MANUFACTURING EQUIPMENT AND HEAT EXCHANGER COMPRISING THEREOF

(71) Applicants: Contamination Control services Inc., Kanagawa (JP); Epicrew Corporation, Nagasaki (JP)

(72) Inventor: Toyohiko SHINDO, Kanagawa (JP)

(21) Appl. No.: 14/605,470

(22) Filed: Jan. 26, 2015

(30) Foreign Application Priority Data
Jan. 27, 2014 (JP) 2014012461

(51) Int. Cl. F04D 19/04; H01L 21/67

(52) U.S. Cl. CPC F04D 19/04; H01L 21/67017

(57) ABSTRACT

An object of the present invention is to provide a rotating flow generator which is capable of preventing a pipe arrangement from clogging. A rotating flow generator 20 includes a shaft 22 and guide blades 23 secured to the shaft 22. When a current of a processed gas flows from upstream, the blades 23 deflect the air current diagonally in a circumferential direction along the formed shape of the blades 23. The substrate processed gas is controlled in direction by colliding with an inner wall surface of a gas discharge pipe 10, and forms a rotating flow S, which circles at a predetermined pitch along the inner wall surface. This rotating flow collides with the inner wall surface of the pipe 10, thereby suppressing deposition of reaction byproducts of the processed gas on the inner wall surface of the pipe 10.

The present application claims priority under 35 U.S.C. §119 to Japanese Patent Application No. 2014-012461 filed on Jan. 27, 2014. The content of the application is incorporated herein by reference in its entirety.

### BACKGROUND OF THE INVENTION

1. Field of the Invention

The present invention relates to a rotating flow generator, as well as a plumbing system, a semiconductor manufacturing apparatus and a heat exchanger comprising thereof.

2. Related Art

For example, an exhaust pipe of a semiconductor manufacturing apparatus for performing process using a reactant gas is likely to clog, since matter such as reaction byproducts is included in an exhaust gas. A method for preventing the clogging is available, in which a planar heater is wound around an exhaust pipe to be heated, to make it difficult for byproducts to attach (Patent Document 1: Japanese Unexamined Patent Application, Publication No. 2007-250696).

Another method is available, in which a high-temperature diluent gas is caused to flow through an inner part of an exhaust pipe, to decompose byproducts, which are flushed out together with the diluent gas (Patent Document 2: Japanese Unexamined Patent Application, Publication No. 2004-165584).

A further method is available, in which a cylindrical nozzle with a blocked head is attached to an inner part of an exhaust pipe; an air outlet is formed in a side face of the cylindrical nozzle; and a fluid is caused to flow through the cylindrical nozzle to generate a cyclone flow, thereby preventing clogging by the cyclone flow (Patent Document 3: Japanese Unexamined Patent Application, Publication No. 2011-141024).

### SUMMARY OF THE INVENTION

According to the prior art disclosed in Patent Document 1, high temperature would, in theory, eliminate attachment of matter inside a pipe wall. However, there are actually various kinds of components, which make it difficult to achieve high temperature capable of preventing attachment of matter inside a pipe wall, and as a result, clogging occurs.

According to the prior art disclosed in Patent Document 2, the flow rate is significantly slowed down along the pipe wall, reducing the temperature of the pipe wall, and as a result clogging occurs.

Furthermore, according to the prior art disclosed in Patent Document 3, the air outlet is narrow resulting in significant pressure loss.

A problem to be solved by the present invention is to provide a rotating flow generator, as well as a plumbing system, a semiconductor manufacturing apparatus and a heat exchanger comprising the same, which are capable of more satisfactorily preventing a pipe arrangement from clogging.

In order to so solve the problem, one aspect of the present invention is a rotating flow generator (20, 20′), which is provided with a shaft (22) and a guide blade (23) secured to the shaft (22).

The rotating flow generator (20, 20′) may be provided with a flange, which is arranged on an outer circumference side of the guide blade (23), and which extends in a continuous manner from at least a part of the guide blade (23) to the outer circumference side; in which an outer periphery of the flange may be a curved face for receiving an O-ring.

The rotating flow generator (20′) may be provided with a cylindrical portion (21) on an outer circumference of the guide blade (23), in which the flange may extend from one end of the cylindrical portion to the outer circumference side.

In the rotating flow generator (20′), the cylindrical portion (21) may be provided with: a first portion in which the guide blade (23) is provided internally; and a second portion extending from the first portion.

In the rotating flow generator (20, 20′), a plurality of guide blades (23) may be provided; and the guide blades (23) may be at different angles in portions connecting the guide blades (23) and the cylindrical portion (21), in relation to a line of intersection between a plane orthogonal to the shaft and the cylindrical portion (21) on the outer circumference of the guide blades (23).

In the rotating flow generator (20, 20′), the shaft (22) may be provided with a columnar portion (22a) and conical portions (22F, 22R) provided to ends of the columnar portion (22a); and an apex angle of one (22F) of the conical portions may be 120 degrees.

The rotating flow generator (20, 20′) may be attached to an inner part of a pipe arrangement (10).

A sensor (51) for detecting a state of a fluid flowing through the pipe arrangement (10) may be attached to a plumbing system.

In the plumbing system, the sensor (51) may detect sound of the fluid flowing through the pipe arrangement (10).

Another aspect of the present invention is a semiconductor manufacturing apparatus (1), which is provided with the plumbing system.

A further aspect of the present invention is a heat exchanger, which is provided with the plumbing system.

The aforementioned features may be improved as appropriate, and at least a part of the features may be substituted with other features.

According to the present invention, it is possible to provide a rotating flow generator, as well as a plumbing system, a semiconductor manufacturing apparatus and a heat exchanger comprising thereof, which are capable of satisfactorily preventing a pipe arrangement from clogging.

### BRIEF DESCRIPTION OF THE DRAWINGS

FIG. 1 is a conceptual configuration diagram of a semiconductor manufacturing apparatus, to which an embodiment of a rotating flow generator according to the present invention is applied;

FIG. 2 is a perspective view showing the appearance of the rotating flow generator;

FIG. 3A is a front view of the rotating flow generator observed from an upstream side;

FIG. 3B is a sectional view along B-B of FIG. 3A;

FIG. 4 is a diagram for illustrating a structure for mounting the rotating flow generator to a gas discharge pipe, and a rotating flow generated by the rotating flow generator;

FIG. 5 is a diagram for illustrating a structure for mounting a rotating flow generator according to a second embodiment to a gas discharge pipe, and a rotating flow generated by the rotating flow generator; and

FIG. 6 is perspective view showing the appearance of a rotating flow generator according to a modified embodiment.

### DETAILED DESCRIPTION OF THE INVENTION

Embodiments of the present invention are hereinafter described with reference to the drawings.

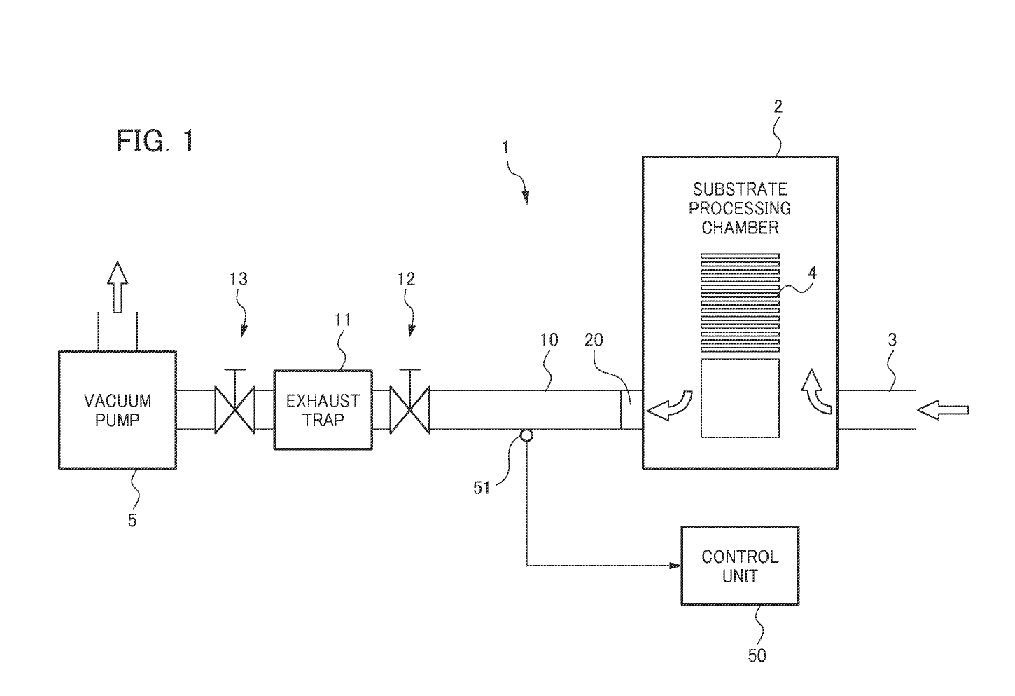

FIG. 1 is a conceptual configuration diagram of a semiconductor manufacturing apparatus 1, to which an embodiment of the rotating flow generator according to the present invention is applied.

The semiconductor manufacturing apparatus 1 shown in FIG. 1 is configured by connecting a gas supply pipe 3 and a gas discharge pipe 10 to a substrate processing chamber 2.

Although detailed descriptions are omitted herein, the substrate processing chamber 2 is formed of quartz or the like, a lower portion of which is provided with an opening that is openable and closable by way of a flange. A substrate 4 to be processed is loaded to, or unloaded from, the substrate processing chamber 2 through the opening.

The gas supply pipe 3 is connected to the lower portion on one side (right side in FIG. 1) of the substrate processing chamber 2. The gas supply pipe 3 supplies a substrate processing gas to the substrate processing chamber 2.

The gas discharge pipe 10 is connected to the lower portion on another side (left side in FIG. 1) of the substrate processing chamber 2. A downstream side of the gas discharge pipe 10 is connected to a vacuum pump 5. The gas discharge pipe 10 is provided with an exhaust trap 11, upstream and downstream sides of which valves 12 and 13 are arranged, respectively.

The vacuum pump 5 is driven to exhaust, through the gas discharge pipe 10, a substrate processed gas and the like, which are generated in reaction with the substrate processing chamber 2.

The exhaust trap 11 cools, deposits and removes reaction byproducts, etc. from the substrate processed gas, which is discharged from the substrate processing chamber 2, and which flows through the gas discharge pipe 10. The exhaust trap 11 can be replaced by closing the valves 12 and 13 provided upstream and downstream thereof, thereby making it possible to collect the trapped reaction byproducts.

The semiconductor manufacturing apparatus 1 having the configuration described above performs deposition process on the substrate through the following actions.

That is, the substrate 4 is placed inside the substrate processing chamber 2; temperature and pressure inside the substrate processing chamber 2 are adjusted; and the substrate processing gas is supplied through the gas supply pipe 3 to the substrate processing chamber 2.

As a result, the substrate processing gas, which is supplied to the substrate processing chamber 2, is heated and reacted to generate a deposition component, which is deposited on the surface of the substrate 4. For example, a mixed gas of SiH₂Cl₂ and NH₃ is used as the substrate processing gas; and Si₃N₄ (silicon nitride), which is a deposition component generated by reaction, is deposited on the surface of the substrate 4.

The substrate processed gas, which has reacted in the substrate processing chamber 2, is suctioned and discharged through the gas discharge pipe 10 by driving the vacuum pump 5. At this time, the exhaust trap 11 traps and collects in mid-course the reaction byproducts included in the substrate processed gas.

HCl is generated in the abovementioned reaction, and the generated HCl is coupled with NH₃ (ammonium) in the second order reaction to become NH₄Cl (ammonium chloride), resulting in reaction byproducts and the like together with other reaction components.

The exterior of the gas discharge pipe 10 is provided with a sensor 51 for detecting a clogging status of the substrate processed gas flowing through the gas discharge pipe 10, and information detected from which is input into a control unit 50 for executing integrated control of the semiconductor manufacturing apparatus 1.

In the present embodiment, the sensor 51 is a sound sensor for detecting sound generated from the gas discharge pipe 10. The sensor 51 monitors sound over time, and detects clogging on the basis of change in the sound.

However, the sensor 51 is not limited thereto; sensors 51 may be provided in the upstream and downstream sides of the gas discharge pipe 10 to detect clogging on the basis of difference in sound between the upstream and downstream sides.

In this manner, the sensor 51 for detecting sound can be attached to the exterior of the gas discharge pipe 10, can detect clogging, and can therefore be easily set up and does not disturb the flow in the gas discharge pipe 10.

Furthermore, the sensor 51 is not limited to a sound sensor, and may be a sensor for detecting vibration, or may be a sensor for detecting pressure and/or temperature inside the gas discharge pipe 10.

The control unit 50 controls the semiconductor manufacturing apparatus 1, by predicting when the gas discharge pipe 10 would be clogged with reaction byproducts (or when the exhaust trap 11 should be replaced) on the basis of information input from the sensor 51.

### First Embodiment

Here, a connection between the gas discharge pipe 10 and the substrate processing chamber 2, i.e. an inlet part of the gas discharge pipe 10, is provided with a rotating flow generator 20, which is an embodiment of the present invention.

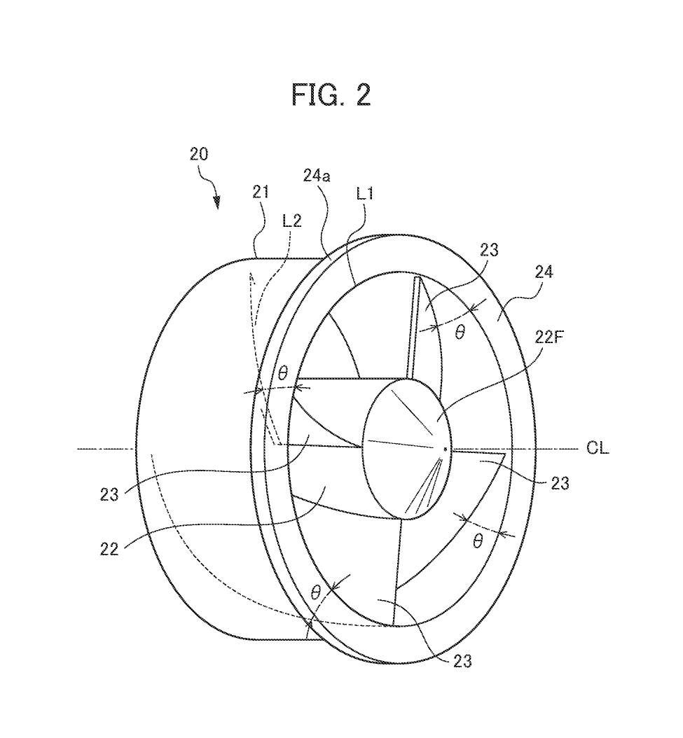

Next, the rotating flow generator 20 is described with reference to FIGS. 2 to 4, in addition to FIG. 1 described above.

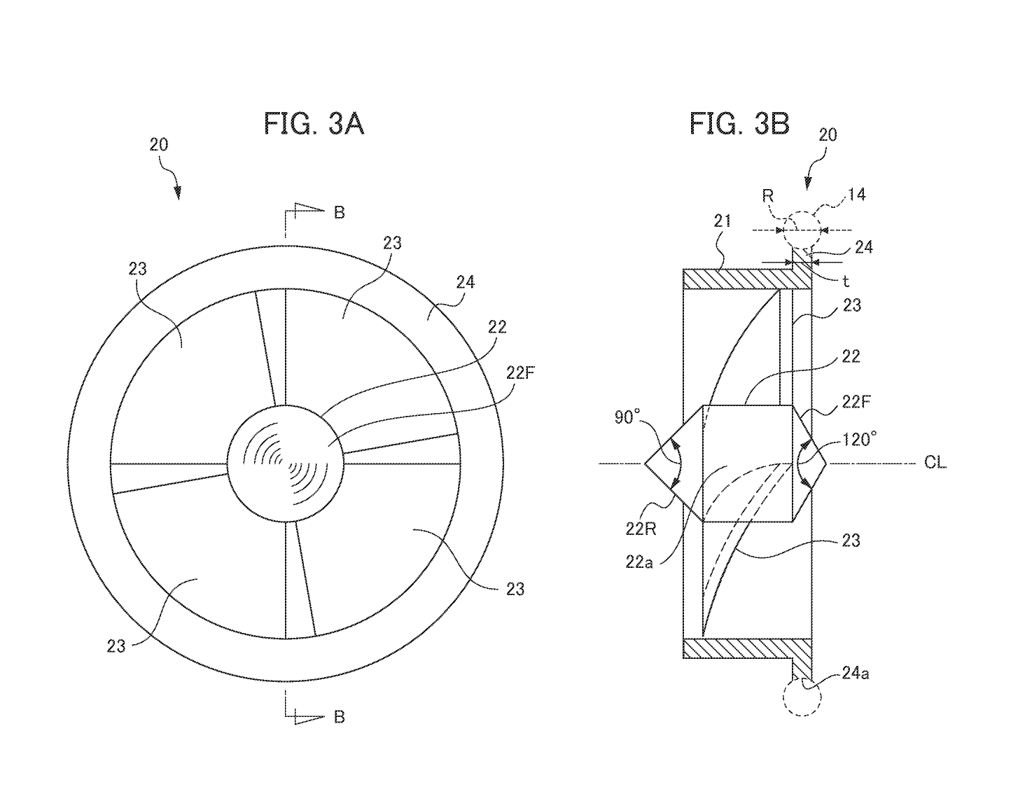

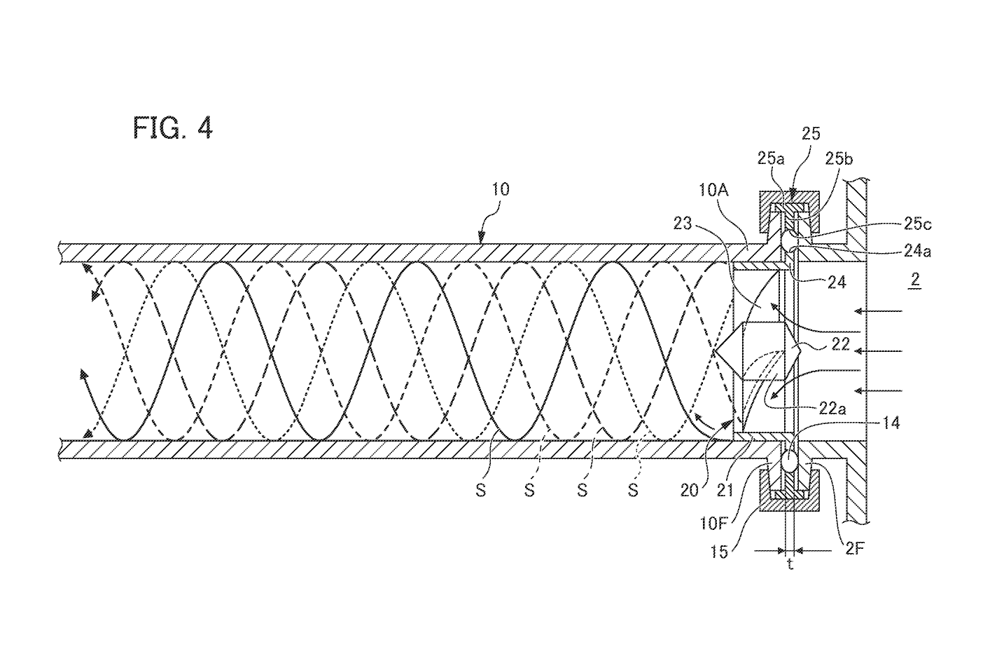

FIG. 2 is a perspective view showing the appearance of the rotating flow generator 20. FIG. 3A is a front view of the rotating flow generator 20 observed from the upstream side; and FIG. 3B is a sectional view along B-B of FIG. 3A. FIG. 4 is a diagram for illustrating a structure for mounting the rotating flow generator 20 to the gas discharge pipe 10, and a rotating flow generated by the rotating flow generator 20.

As shown in FIGS. 2 and 3, the rotating flow generator 20 is provided with: a cylindrical portion 21; a flange 24 formed at one end thereof; a shaft 22 located in the center of the cylindrical portion 21; and four guide blades 23 provided between the cylindrical portion 21 and the shaft 22. The rotating flow generator 20 is arranged such that the right side in FIGS. 2 and 3B is the upstream side (the substrate processing chamber 2 side).

The cylindrical portion 21 has a thin-walled short cylinder shape, with an outer diameter sized to allow insertion thereof into the gas discharge pipe 10 leaving no gap (to be described later).

The shaft 22 has a column shape with a predetermined diameter. The guide blades 23 (to be described later) integrally join the front and rear ends of a columnar portion 22a, which are respectively provided with conical portions (front end conical portion 22F, and rear end conical portion 22R).

In this manner, the rotating flow generator 20 of the present embodiment has the cylindrical portion 21; however, the rotating flow generator 20 is not limited thereto, and may not have the cylindrical portion 21 on the outer circumference of the blades 23.

An apex angle of the front end conical portion 22F facing the upstream side is set to 120 degrees; and an apex angle of the rear end conical portion 22R facing the downstream side is set to 90 degrees.

The apex angle of the front end conical portion 22F facing the upstream side is set to 120 degrees, thereby making it possible to smoothly introduce the fluid flow into the guide blades 23 without causing any turbulence, etc.

The apex angle of the rear end conical portion 22R facing the downstream side is set to 90 degrees, thereby making it possible to smoothly guide the rotating flow, which is formed by the guide blades 23, to the inner wall of the pipe without causing any turbulence, etc.

The four guide blades 23 each have a thin sheet shape, and are provided between the inner wall of the cylindrical portion 21 and the outer periphery of the shaft 22, at equal intervals in the circumferential direction (i.e. at an interval of 90 degrees). The guide blades 23 are provided so as to connect the outer periphery of the shaft 22 to the inner periphery of the cylindrical portion 21. In other words, the four guide blades 23 support the shaft 22 at the center of the cylindrical portion 21.

As shown in FIG. 2, a line of intersection L1, which is an intersection of the cylindrical portion 21 with a surface orthogonal to an axis CL of the cylindrical portion 21, is tilted at an angle θ (e.g., θ=20 degrees) in relation to a connecting portion L2 between the guide blade 23 and the cylindrical portion 21. In the present embodiment, the angle θ is equally set for all of the four guide blades 23.

With respect to the flange 24, which extends from one end side toward an outer diameter side of the cylindrical portion 21, an outer periphery 24a (the externally facing surface) of the flange 24 is curved, as shown in FIG. 3. An O-ring 14 is arranged and retained on the outer periphery 24a. That is, the flange 24 has a function of an inner ring for positioning the O-ring 14.

As shown in FIG. 3, thickness t of the flange 24 is smaller than thickness R of the O-ring 14. As shown in FIG. 3, the thickness of the O-ring 14 is the cross-sectional diameter of a member forming the O-ring 14.

As shown in FIG. 4, an outer ring 25 is arranged on the outer circumference of the O-ring 14. The outer ring 25 is a circular ring member with a T-shaped cross section, and includes an outer annular portion 25a and an inner annular portion 25b extending from the inner central portion of the outer annular portion 25a toward the inner diameter side. The thickness of the inner annular portion 25b is thickness t, which is the same as the thickness of the flange 24, and which is smaller than the thickness R of the O-ring 14.

An end face 25c of the inner annular portion 25b is curved similarly to the outer periphery 24a of the flange 24. The O-ring 14 is interposed between the outer periphery 24a of the flange 24 and the end face 25c of the outer ring 25.

As shown in FIGS. 1 and 4, the rotating flow generator 20 is arranged in the inlet of the gas discharge pipe 10 (connection part between the substrate processing chamber 2 and the gas discharge pipe 10: position where the substrate processed gas from the substrate processing chamber 2 flows in).

At this time, the cylindrical portion 21 of the rotating flow generator 20 is inserted into the gas discharge pipe 10; however, the flange 24, which is larger than the inner diameter of the gas discharge pipe 10, is not inserted therein. Therefore, the entire rotating flow generator 20 is prevented from penetrating deeply into the gas discharge pipe 10 making removal difficult.

As shown in FIG. 4, a connecting flange 10F, which is provided to an outer circumference of the end of the gas discharge pipe 10, and a securing flange 2F, which is provided to an outlet of the substrate processing chamber 2, are arranged to oppose each other, interposing the flange 24, the O-ring 14, and the inner annular portion 25b of the outer ring 25 therebetween, and are tightened by a clamp 15 from the outer circumference side.

With respect to the connecting flange 10F and the securing flange 2F, sloping faces opposite to the mutually opposed sides are tapered, so that the thickness decreases toward the outer circumference side.

On the other hand, the inner surface side of the clamp 15 is tapered, so that the thickness decreases from the outer circumference side toward the inner circumference side.

Therefore, when the clamp 15 is tightened toward the inner diameter side, the connecting flange 10F and the securing flange 2F are depressed to approach each other.

At this time, the thickness R of the O-ring 14 is larger than the thickness t of the inner annular portion 25b of the outer ring 25, and is larger than the thickness t of the flange 24. Therefore, when the clamp 15 is tightened toward the inner diameter side, the connecting flange 10F and the securing flange 2F are pressed to approach each other, thereby deforming the O-ring 14.

In this case, since the position of the O-ring 14 is secured by the flange 24, the O-ring 14 does not deviate when tightened, and the side faces of the O-ring 14 are pressed against the connecting flange 10F and the securing flange 2F, thereby hermetically connecting the gas discharge pipe 10 and the substrate processing chamber 2.

In this manner, the rotating flow generator 20, which is attached to the inlet of the gas discharge pipe 10, functions as follows.

In the rotating flow generator 20, a current of the substrate processed gas flows from upstream; the front end conical portion 22F of the shaft 22 radially deflects the current toward the perimeter (in a direction colliding with the inner wall surface of the gas discharge pipe 10); and the guide blades 23 further deflect the current diagonally in a circumferential direction along the formed shape of the guide blades 23.

That is, the guide blades 23 deflect the current of the substrate processed gas in a tangential direction to a circle around the axis CL, in a plane orthogonal to the axis CL; and deflect the current at an angle of the guide blades 23, in a direction parallel to the axis CL. The rear end conical portion 22R of the shaft 22 causes the current to smoothly converge in the downstream side of the shaft 22.

As a result, the substrate processed gas, which flows through the gas discharge pipe 10 in the downstream side of the rotating flow generator 20, is controlled in direction by colliding with the inner wall surface of the gas discharge pipe 10, and forms a rotating flow S, which circles at a predetermined pitch along the inner wall surface, as shown in FIG. 4. The four guide blades 23 are provided at an interval of 90 degrees in the circumferential direction, and therefore form four rotating flows like a quadruple-threaded screw, which has the same pitch at different phases at 90 degrees; and the four rotating flows converge.

The substrate processed gas, which flows as the rotating flow through the gas discharge pipe 10, collides with the inner wall surface of the gas discharge pipe 10, and destroys a boundary layer formed on the surface thereof (or prevents the boundary layer from being formed). This makes it possible to suppress the deposition of reaction byproducts, such as ammonium chloride included in the substrate processed gas, which are generated by reduction in flow velocity and temperature due to the boundary layer. The current can remove matter such as reaction byproducts attached to the inner wall surface.

As a result, it is possible to suppress the clogging of the gas discharge pipe 10 due to matter such as reaction byproducts attached to the inner wall surface, reduce the frequency of maintenance and down time therefor, and improve the operation efficiency of the semiconductor manufacturing apparatus 1.

Furthermore, the rotating flow generator 20 is provided with the flange 24, and the flange 24 has a function of an inner ring; therefore, the O-ring 14 can be retained without using an inner ring as a separate member.

The thickness t of the flange 24 is smaller than the thickness R of the O-ring 14; therefore, the O-ring 14 can be deformed under compression when tightened by the clamp, and the gas discharge pipe 10 and the substrate processing chamber 2 can be hermetically connected.

### Second Embodiment

Next, a second embodiment of the rotating flow generator according to the present invention is described.

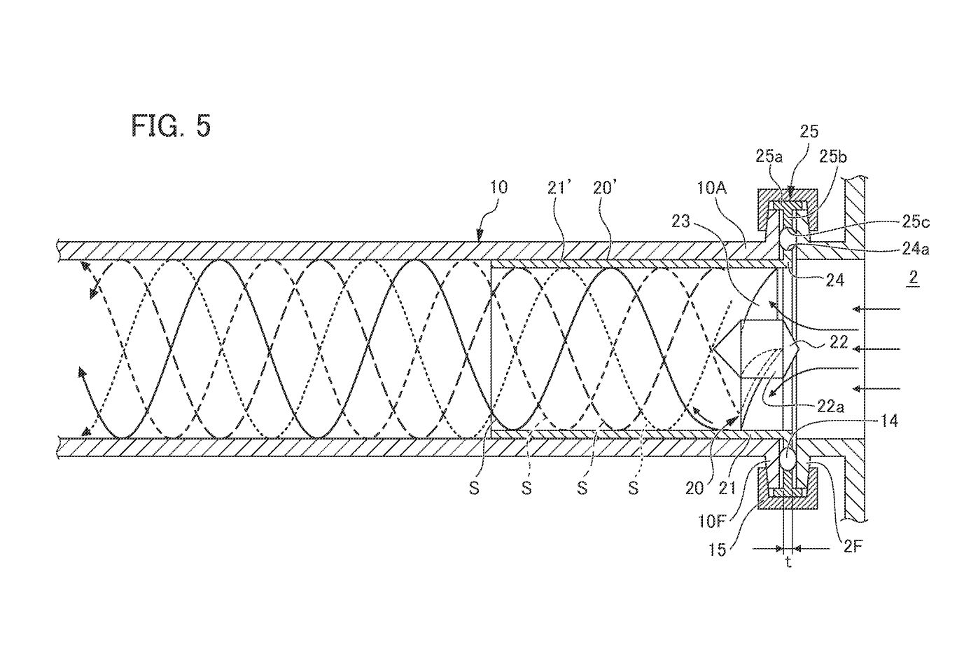

FIG. 5 is a perspective view showing the appearance of a rotating flow generator 20′ according to the second embodiment. Note that a basic configuration and a mounting structure of the rotating flow generator 20′ of the second embodiment are similar to those of the first embodiment described above, in which constituent elements having the same functions are assigned with the same reference numerals, and descriptions thereof are omitted.

In the second embodiment, a cylindrical portion 21′ is longer than a portion including blades 23, which is a point of difference from the first embodiment.

According to the first embodiment, it is possible to suppress deposition and adhesion of matter such as reaction byproducts included in the gas, on the inner wall surface inside the gas discharge pipe 10, but there is a possibility that a small amount of the reaction byproducts may attach to the inner wall surface of the gas discharge pipe 10.

However, according to the present embodiment, the cylindrical portion 21′ of the rotating flow generator 20′ is elongated.

When maintenance is performed, the clamp 15 is removed, and the connecting flange 10F, which is provided to the outer circumference at the end of the gas discharge pipe 10, the securing flange 2F and the gas discharge pipe 10, which are provided to the outlet of the substrate processing chamber 2, and the connection are separated from one another.

At this time, the rotating flow generator 20′ is pulled off the cylinder to clean only the rotating flow generator 20′, thereby making it possible to remove the reaction byproducts attached to the elongated cylindrical portion 21.

This facilitates removal of the reaction byproducts attached to the inner wall of the gas discharge pipe 10.

### Modified Embodiments

The present invention is not limited to the embodiments described above, and various modifications and changes as described below are also possible within the scope of the present invention.

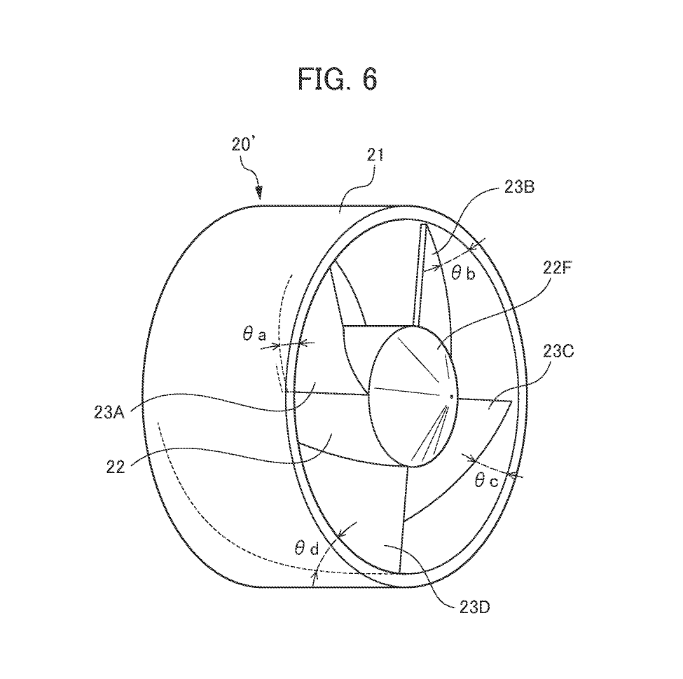

(1) In the embodiments described above, the angle θ is the same for all the four guide blades 23A, 23B, 23C and 23D, which are provided between the inner wall of the cylindrical portion 21 and the outer periphery of the shaft 22, the angle θ being defined by the connecting portion L2 between the guide blade 23 and the cylindrical portion 21, in relation to the line of intersection L1, which is the intersection of the cylindrical portion 21 with a surface orthogonal to the axis CL; however, the present invention is not limited thereto. For example, as shown in FIG. 6, all of angles θa θb, θc and θd of the connecting portion L2 in relation to the guide blades 23 and the cylindrical portion 21 may be made different (FIG. 6 shows the angles as θa<θb<θc<θd); or any one or two of the angles θa, θb, θc and θd may be made different.

According to this, guide blades 23A, 23B, 23C and 23D generate rotating flows Sa, Sb, Sc and Sd of the substrate processed gas, having different pitches, respectively. By appropriately setting the pitches of the rotating flows Sa, Sb, Sc and Sd of the substrate processed gas, it is also possible to cause the rotating flows to efficiently collide with the inner wall surface of the gas discharge pipe 10.

The blades are preferably provided without any gap, in which an angle of the blades is determined by an inner diameter and length of the cylindrical portion.

(2) In the present embodiment, the rotating flow generator 20 is provided with the four guide blades. However, the number of the guide blades is not limited thereto, and may be greater or smaller than this number. For example, a configuration may be provided with one to sixteen (preferably two to eight) guide blades.

(3) In the present embodiment, the single rotating flow generator 20 is provided to the inlet portion of the gas discharge pipe 10. However, the number and position for arranging the rotating flow generator 20 are not limited thereto, and can be set as appropriate, such as, for example, by arranging the rotating flow generators 20 in two positions in the inlet and the middle of the pipe line.

(4) The present embodiment is an example of providing the rotating flow generator 20 to the gas discharge pipe 10, but the rotating flow generator 20 may be provided to the gas supply pipe 3 for supplying the reactant gas.

(5) The present embodiment suppresses adhesion of components (such as reaction byproducts) of the carriage gas (the substrate processed gas) to the inner wall of the pipe line (the gas discharge pipe 10) by the rotating flows generated by the rotating flow generator 20. However, the rotating flow generator of the present invention may be applied to a pipe line of a heat carrier in a heat exchanger. According to this, the rotating flow destroys a boundary layer of the inner wall surface of the pipe line, thereby making it possible to improve the efficiency of heat exchange.

(6) Furthermore, the embodiments are described above for the case in which a gas flows as a fluid; however, the present invention is not limited thereto. For example, a liquid or a solid with fluidity such as a powder is possible.

Note that the embodiments and the modified embodiments can be used in combination as appropriate; however, detailed descriptions thereof are omitted herein. The present invention is not limited by the embodiments described above.

What is claimed is:

1. A rotating flow generator, comprising:
a shaft; and
a guide blade secured to the shaft.

2. The rotating flow generator according to claim 1, further comprising:
a flange, which is arranged on an outer circumference side of the guide blade, and which extends in a continuous manner from at least a part of the guide blade to the outer circumference side;
wherein an outer periphery of the flange is a curved face for receiving an O-ring.

3. The rotating flow generator according to claim 2, further comprising:
a cylindrical portion on an outer circumference of the guide blade;
wherein the flange extends from one end of the cylindrical portion to the outer circumference side.

4. The rotating flow generator according to claim 3,
wherein the cylindrical portion comprises: a first portion in which the guide blade is provided internally; and a second portion extending from the first portion.

5. The rotating flow generator according to claim 1,
wherein a plurality of the guide blades are provided; and
wherein the guide blades are provided at different angles in portions connecting the guide blades and the cylindrical portion, in relation to a line of intersection between a plane orthogonal to the shaft and the cylindrical portion on the outer circumference of the guide blades.

6. The rotating flow generator according to claim 1,
wherein the shaft comprises a columnar portion and conical portions provided to ends of the columnar portion; and
wherein an apex angle of one of the conical portions is 120 degrees.

7. A plumbing system, wherein the rotating flow generator according to claim 1 is attached to an inner part of a pipe arrangement.

8. The plumbing system according to claim 7,
wherein a sensor for detecting a state of a fluid flowing through the pipe arrangement is attached.

9. The plumbing system according to claim 8,
wherein the sensor detects sound of the fluid flowing through the pipe arrangement.

10. A semiconductor manufacturing apparatus, comprising the plumbing system according to claim 7.

11. A heat exchanger, comprising the plumbing system according to claim 7.
